(19) United States
(12) Patent Application Publication
(10) Pub. No.: US 2025/0112266 A1
(43) Pub. Date: Apr. 3, 2025

(54) SURFACE CLEANING, MODIFICATION AND DOPING OF ARGYRODITE TYPE SOLID ELECTROLYTES

(71) Applicant: UCHICAGO ARGONNE, LLC, Chicago, IL (US)

(72) Inventors: Anil U. Mane, Naperville, IL (US); Zachary David Hood, Bolingbrook, IL (US); Jeffrey W. Elam, Elmhurst, IL (US)

(73) Assignee: UCHICAGO ARGONNE, LLC, Chicago, IL (US)

(21) Appl. No.: 18/478,961

(22) Filed: Sep. 29, 2023

(51) Int. Cl. H01M 10/0562; C23C 16/02; C23C 16/40; C23C 16/44; C23C 16/455

(52) U.S. Cl. CPC H01M 10/0562; C23C 16/0236; C23C 16/403; C23C 16/4408; C23C 16/45527; C23C 16/45555; H01M 2300/008; H01M 2300/0094

(57) ABSTRACT

A method for modifying argyrodite-type material. The argyrodite-type material is exposed to a fluorine precursor. The argyrodite-type material may have a carbonate coating that has formed, such as due to exposure to air, with such carbonate coating at least partially removed by exposure to the fluorine precursor. The argyrodite-type material may further be doped by fluorine after exposure to the precursor. Further, the argyrodite-type material may have a capping layer formed thereon.

### STATEMENT OF GOVERNMENT INTEREST

This invention was made with government support under Contract No. DE-AC02-06CH11357 awarded by the United States Department of Energy to UChicago Argonne, LLC, operator of Argonne National Laboratory. The government has certain rights in the invention.

### TECHNICAL FIELD

The present disclosure relates to solid electrolytes, particularly argyrodite type solid electrolytes.

### BACKGROUND

Solid-state batteries (“SSB”) demonstrate great potential for improved safety as they replace the flammable liquid electrolyte in conventional Li- and Na-ion batteries with a solid electrolyte that can operate over a wider temperature window. Currently rapid development of solid-state electrolytes (“SSE”) has been driven by the successful exploration for materials that are superionic Li, Na and Mg conductors at room temperature. One type of material under consideration for SSE is argyrodite-type materials. The term “argyrodite-type” would be understood to refer to the category of materials having a similar structure to silver germanium sulfide mineral commonly referred to as “argyrodite”. More specifically, the argyrodite-type materials take the form of Li₇₋ₓBCh₆₋ₓXₓ, where 0<x<1, B is phosphor or arsenic, Ch is a chalcogen such as sulfur or selenium, X is a halide. The general chemical formula for class of argyrodite-type solid electrolyte can be written as M-P-S-X (where M=Li, Mg, Na, Ca, and X=halide such as F, Br, Cl, I, or combinations thereof, for example X is Cl and Br in a 1:1 ratio). For example, lithium argyrodites with the composition of Li₆PS₅Cl have shown a high ionic conductivity of up to 1.5×10⁻² S/cm which is several orders better than best known material LiPON ionic conductivity (˜10⁻⁶ S/cm) at room temperature.

However, argyrodite-type materials are highly air sensitive which is major safety and ease-of-use issue. Therefore, there is a need to handle such materials in a controlled environment, such as in the glove box inert environment. However, given their reactivity and sensitivity to air, improving their stability again air and moisture if great topic of interest for the commercial point of view and many efforts along these directions are in progress. Somewhat related to this reactivity and difficulty in handling the material, argyrodite-type materials, as well as most of the battery materials for advanced cathodes or solid electrolytes, are known to form surface carbonate during wet synthesis method or during off the shelf storage period which also affect the performance of these materials/batteries.

SSB are of increasingly widespread use. SSB face a particular challenge in the high interfacial impedance that exists between the SSE and the anode or cathode. Naturally formed lithium carbonate further increases the interfacial impedance. Reducing the impedance through removal of the lithium carbonate and preventing the formation of further lithium carbonate is desirable but not practically achieved.

There have been numerous attempts at addressing the high interfacial impedance generally in SSBs. One approach has been the removal of lithium carbonate followed by the formation of a protective coating on the SSE. However, such current methods have undesirable attributes, such as being multi-step processes or exhibiting poor scalability to industrial scale use. The multi-step aspect of the existing processes also can allow for formation of lithium carbonate (Li₂CO₃) after removal in the first step but before the protective coating can be formed. The removal of lithium carbonate is typically done by physically stripping off the Li₂CO₃ layer using a brush or other physical interactions. This method is not scalable and practical to apply to industrial process.

However, there remains a need for an argyrodite-type material that is functional as a SSE or generally in a SSB that minimizes or avoid the issues relating to handling in a controlled environment and having impendence issues due in part to lithium carbonate.

### SUMMARY

In one embodiment, a single vapor precursor may be exposed to the argyrodite-type material for one or more of surface cleaning, doping, and/or surface modification. The chemical vapor treatment utilizes the simultaneous etching or removal of material, such as by removal of carbon and oxygen, and the deposition of metal F to form the Li-F-O composite layer, a fluorine doped argyrodite-type material having carbonate removed.

In some embodiments, an ALD approach may be utilized. A first metal precursor is exposed in an ALD reactor to the argyrodite-type material, with the metal binding with a carbonate on the argyrodite-type material or the argyrodite-type material itself. Fluorine precursors are exposed in the ALD reactor to react with the bound metal of the first precursor, effectively etching away the carbonate to layer or reacting with the metal bound to the argyrodite-type material to form a fluorine doped argyrodite-type material.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE FIGURES

The foregoing and other features of the present disclosure will become more fully apparent from the following description and appended claims, taken in conjunction with the accompanying drawings. Understanding that these drawings depict only several implementations in accordance with the disclosure and are, therefore, not to be considered limiting of its scope, the disclosure will be described with additional specificity and detail through use of the accompanying drawings.

FIG. 1 is a graph of x-ray photoelectron spectroscopy (“XPS”) data for a commercially available argyrodite-type material Li₆PS₅Cl.

FIG. 2 is a graph of representative sample XPS data based on experimental exposures to the indicated chemistry in comparison to pristine argyrodite-type material.

FIG. 3 is a graph of Li ion conductivity of the tested samples measured using electrochemical impedance spectroscopy.

FIG. 4 is an activation energy graph for Li ion conductivity of the tested samples.

FIG. 5 is a graph of electronic conductivity measured by applying a 0.2 V DC voltage across an argyrodite pellet at 25° C.

FIG. 6 is a graph of voltage versus time by applying 0.5 mA/cm² to a Li|SSE|Li symmetric cell at 25° C.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

This invention comprises a method of surface treating argyrodite-type materials, such as a simple single precursor vapor phase processing method or/and atomic layer deposition (“ALD”) method. Embodiments described herein modify argyrodite-type materials wors in terms of removed the surface carbonate, improving material stability by surface modification, and introducing F-dopant in the argyrodites structure. Argyrodite-type solid electrolytes of the type (M-P-S-X) (where M=Li, Mg, Na, and Ca; X=F, Cl, Br and/or I, where more than one halide may be present in a given argyrodite sample). In specific embodiments, lithium argyrodites with the composition of Li₆PS₅Cl are cleaned, modified, and/or doped by precursor vapor phase processing methods. Examples included herein provide experimental results for commercially purchased argyrodite-type materials. As further described below, argyrodite materials can be selectively modified by adjusting processing parameters, such as processing temperature, precursor nature, processing time, and the ALD precursor exposure times and the number of ALD cycles.

In one embodiment, the argyrodite-type material is surface cleaned. As used herein, this refers to the removal of material from the argyrodite-type material surface, including an argyrodite solid electrolyte (“ASE”). For example, a carbonate surface layer may form on an ASE comprising pristine argyrodite-type material. This carbonate surface layer may be removed, wholly or partially. Removal of the carbonate surface layer is accomplished by exposure to a vapor phase precursor. The vapor phase precursor (or one of the precursors in embodiments utilizing more than one precursor, such as via an ALD method) reacts with the carbonate surface layer, removing the carbonate layer and exposing the argyrodite-type material to the environment.

In one embodiment, the argyrodite-type material is doped. The dopant may be selected to improve the electrochemical properties (such as voltage window, ionic conductivity, electronic conductivity, critical current density and Arrhenius activation energy) or to improve the ability for at least one of removing a carbonate layer and depositing an encapsulation layer. It should be appreciated that the dopant may be integrated into the ASE without surface cleaning and/or without surface modification by encapsulation. In one embodiment, the dopant is deposited on the argyrodite-type material by the same process used to surface clean the argyrodite-type material. For example, the argyrodite-type material may be doped with F by a single fluorine precursor or an ALD process that includes a fluorine precursor, both of which may also be reactive with any carbonate layer present to remove the carbonate layer as “surface cleaning” while reacting with the exposed argyrodite-type material to form a doped argyrodite-type material such as M-P-S-X-F (where M=Li, Mg, Na, and Ca; X=F, Cl, Br and/or I).

In one embodiment, the argyrodite-type material is surface-modified. The surface modification may include formation of a non-reactive (for example, not reactive in air to form carbonate) layer on the surface of the argyrodite-type material. The surface modification may include a capping layer on the argyrodite-type material surface, for example after cleaning off a formed carbonate layer the capping layer may be deposited directly on the argyrodite-type material surface. Further, it should be appreciated that the surface modification may occur with pristine argyrodite-type material that has not formed a carbonate as well (i.e., without the need for a “cleaning” step). The surface modification may be made to pristine argyrodite-type material or to doped argyrodite-type material.

In one embodiment, a single vapor precursor may be exposed to the argyrodite-type material for one or more of surface cleaning, doping, and/or surface modification. This process is termed chemical vapor treatment (“CVT”) and involves the simultaneous etching or removal of material, such as by removal of carbon and oxygen, and the deposition of F to form a LiF-rich composite layer. This CVT is distinct from chemical vapor deposition (“CVD”) which uses a constant supply of one or more chemical vapors and is purely a deposition process with no surface cleaning. For example, the exposure of a fluoride precursor may remove carbonate, react with the argyrodite-type material to dope the material with fluorine, and form a LiF layer on the surface that functions as a stable capping layer.

In a first step, an ASE is positioned in a reactor. The ASE may include a lithium carbonate layer or film, for example a film that has formed upon exposing the ASE to ambient air. The ASE may be prepared by a number of known methods.

The reactor is heated to 100-350° C., such as 100-250° C., 120-200° C., 1305-170° C., or about 150° C. The reactor may be heated before or after the argyrodite-type material is loaded into the reactor. The reactions will be slower at lower reactor temperatures adding to the process time. However, higher temperatures may damage the argyrodite-type material's structure, compromising the resultant electrode. As such, in one embodiment, the preferred reactor temperature is between 200-300° C. The heating may, in one embodiment, be under a low pressure (0.05-10 Torr, such as 1 Torr) of an inert gas, with the precursor at a pressure of 0.05-0.5 Torr, such as about 0.1 Torr. The inert gas flow velocity should be in the range of 0.1-20 m/s, or preferably 2 m/s, and will help to sweep away contaminants that desorb from the ASE surface and reactor walls that may react with the exposed Cl or any formed F on the argyrodite-type material surface.

In a next step, a CVT is utilized, with a CVT precursor flowed into the reactor, such as with a carrier gas, for a 45-120 second exposure time of the precursor but preferably about 50 seconds. The precursor partial pressure can be in the range of 0.001-10 Torr but preferably in the range of about 0.1 Torr. Generally speaking, longer exposure times can be used with lower precursor partial pressures, and shorter exposure times can be used with higher precursor partial pressures such that the product of exposure time and partial pressure is approximately 2 Torr seconds. Larger exposures may be needed at lower processing temperatures due to the slower CVT kinetics at the lower temperatures. In addition, larger exposures may be needed if CVT is performed on larger batches of the ASE material.

In one embodiment, the specific fluorine related CVT precursor may be selected from hydrogen fluoride (HF), hydrogen fluoride-pyridine (HF-py), hexafluoroacetylacetonate (Hfac), boron trifluoride (BF₃), tungsten hexafluoride (WF₆), molybdenum hexafluoride (MoF₆), tantalum pentafluoride (TaF₅), and niobium pentafluoride (NbF₅). For example, fluorine precursors may be utilized to react, effectively etching or removing, the surface carbonate and/or to modify the surface of the argyrodite-type material, such as by depositing surface F. In some embodiments, rather than a single vapor precursor as described above, a more traditional ALD approach may be used. The ALD approach consists of a cycle, which may be repeated to form a supercycle, with a first metal precursor vapor pulse (e.g., for 5 seconds), followed by a first metal exposure (e.g., for 30 seconds), followed by a first metal precursor purge (e.g., for 1 second) where the reactor is pumped to a vacuum, followed by a co-reactant pulse, (e.g., for 1 second) with a co-reactant exposure (e.g., for 1 second), followed by a co-reactant purge (e.g., for 1 second).

In some embodiments, the first metal precursor vapor pulse comprises input to the reactor of the first metal precursor vapor for a first metal precursor vapor pulse time of 1 seconds to 100 seconds based on the surface area of the argyrodite-type material (e.g., 0.5, 1, 5, 10, 20, or 30 seconds, inclusive of all ranges and values therebetween), such as 5 seconds. The first partial pressure of the first metal precursor vapor pulse can be in the range of 0.01 Torr to 10,000 Torr (e.g., 10, 25, 50, 75, 100, 500, or 1000 Torr, inclusive of all ranges and values therebetween), such as, in one embodiment, at least 0.5 to 100 Torr. One of skill in the art will appreciate that the time length, pressure, and amount of precursor for the pulse are all factors in determining the overall amount for each of those operation parameters.

In some embodiments, the first metal precursor exposure comprises exposing the ASE material to the first metal precursor for a first metal exposure time and a first partial pressure of the first metal precursor so that the first metal precursor binds with the argyrodite-type material and/or carbonate on the argyrodite-type material. The first metal exposure time can be in the range of 0.5 seconds to 500 seconds (e.g., 0.5, 1, 5, 10, 20, 30, 40, 50, 60, 70, 80, 90, 100, 120, 140, 160, 180, 200, 220, 240, 260, 280, 300, 350, 400, 450 or 500 seconds, inclusive of all ranges and values therebetween). In some embodiments, the first predetermined time is in the range of 1 and 10 seconds (e.g., about 5 seconds). The first partial pressure of the first metal precursor can be in the range of 0.01 Torr to 10 Torr (e.g., 0.01, 0.05, 0.1, 0.5, 1.0, 5.0, or 10 Torr, inclusive of all ranges and values therebetween). In some embodiments, the first partial pressure of the first metal precursor is in the range of 0.1 Torr and 1 Torr (e.g., about 0.5 Torr).

The first metal precursor purge evacuates unreacted precursor from the reactor. The first metal precursor purge may be for a first metal precursor purge time of 0.5 seconds to 30 seconds (e.g., 0.5, 1, 5, 10, 20, or 30 seconds, inclusive of all ranges and values therebetween), such as 5 seconds. The first metal precursor purge reduces the pressure in the reactor to within the range of 0.01 Torr to 10 Torr (e.g., 0.01, 0.05, 0.1, 0.5, 1.0, 5.0, or 10 Torr, inclusive of all ranges and values therebetween), such as substantially to vacuum.

In some embodiments, the base material can be heated to a predetermined temperature during the ALD process. For example, the first predetermined temperature can be in the range of 50-200° C. (e.g., 50, 60, 70, 80, 90, 100, 110, 120, 130, 140, 150, 160, 170, 180, 190 or 200° C., inclusive of all ranges and values therebetween). In some embodiments, the predetermined temperature is in the range of 130-170° C. (e.g., 150° C.). Temperature also impacts the overall energy in the system and the performance for diffusion and/or reaction.

In some embodiments, first metal precursor and co-reactant combinations include trimethyl aluminum (TMA) and HF-py to form aluminum fluoride. In further embodiments, the ALD process may include a second metal precursor and a second co-reactant, for example combination of second metal precursor and second co-reactant may be diethyl zinc (DEZ) and H₂O, resulting in the formation of a zinc oxide layer on the ASE forming a barrier or capping layer. In a further embodiment, a single precursor phase may be utilized to remove some or all of the surface carbonate and dope the argyrodite-type material, followed by an ALD process to surface modify the doped argyrodite-type material with a capping layer.

### Experimental Examples

Experiments were undertaken using ALD/CVD precursor vapor phase synthesis at 150° C. to modify argyrodite-type material as described above. The experiments utilized pristine samples, that is unmodified commercial argyrodite-type material, a single fluorine precursor, an ALD pair of precursors for deposition of a metal fluoride (AlF₃ using TMA-HF-py), Al₂O₃, ZrO₂, TiO₂, HfO₂, Nb₂O and an ALD pair of precursors for the deposition of a capping layer (Al₂O₃ using TMA-H₂O).

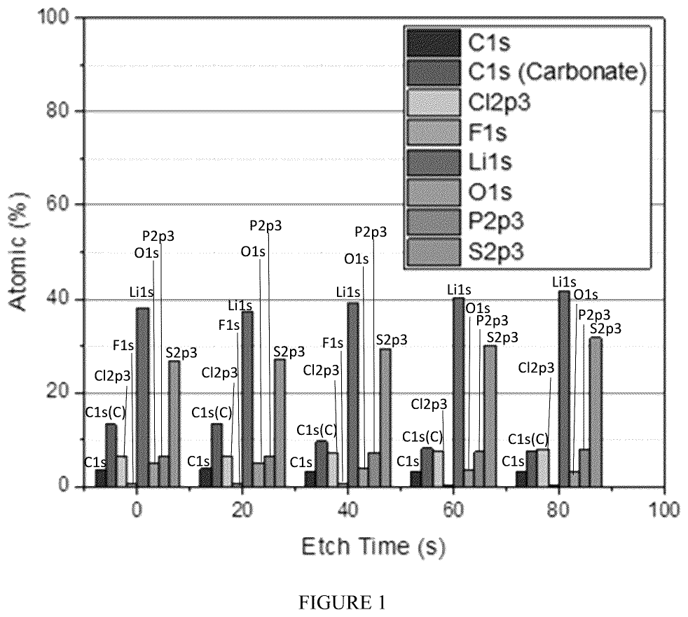

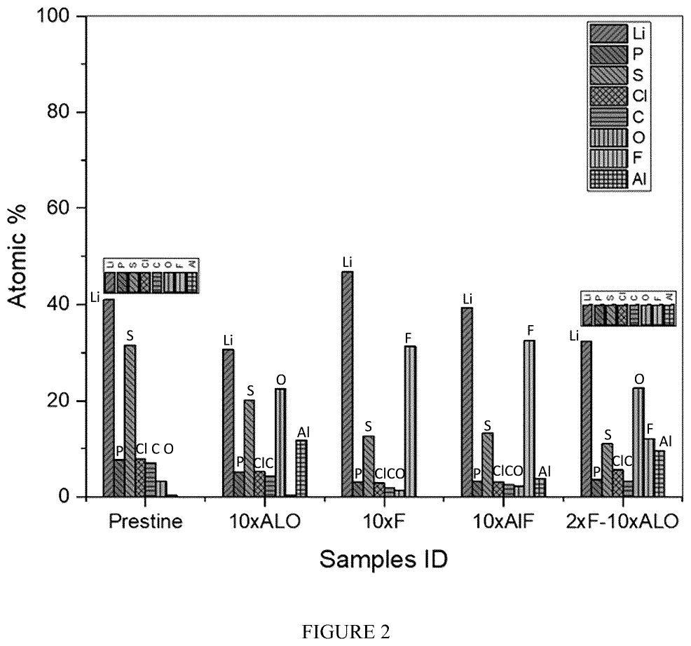

FIG. 1 shows XPS elemental percentage for pristine (Li₆PS₅Cl) used in the experiments versus etch time during XPS depth profiling. FIG. 2 shows XPS elemental percentages with processing chemistries at 150° C. for several embodiments of argyrodite-type material modification. From this XPS data it can be seen that modified lithium argyrodites (Li₆PS₅Cl) is achieved by forming a protecting LiF layer on the surface using F-containing precursors. The formation of this LiF layer, which is stable against air thus preventing further carbonate formation, removed the surface carbonate and substituted Cl with F dopant in controlled manner. The Al₂O₃ALD resulted in the formation of a protective Al₂O₃ coating on the AES surface. Furthermore, the impact of the ALD coating on the ionic conductivity were tested using electrochemical impedance spectroscopy for several experimental approach compared to a control pristine sample of argyrodite-type material (Li₆PS₅Cl). The tested approaches included: 1 nm ALDAl₂O₃ (10xAlO), 10 exposures to HF-py (10xF), 1 nm ALD AlF₃ (10xAlF), and 2 exposures to HF-py followed by 1 nm ALD Al₂O₃ (2xF-10xAlO). In general, S is greatly reduced for all cases and carbonate is reduced for all cases. The F-treated and ALD AlF₃ coated samples show less LiOₓ compared to the ALD Al₂O₃ coated samples (as well as compared to pristine control). Cl content is preserved in the experimental modifications of argyrodite-type material relative to the pristine sample.

Table 1 summarizes the room temperature ionic conductivity of the pristine and coated argyrodites. By selective control of the surface chemistry through ALD, the ionic conductivity can be improved from 0.85 mS/cm (for the pristine argyrodite) to 1.4 mS/cm (for the argyrodite coated with the 2xF-10xAlO chemistry).

TABLE 1

| | Ionic Conductivity (mS/cm) |
|---|---|
| Sample | at 25° C. |
| Pristine Argyrodite | 0.85 |
| 10 × F | 0.70 |
| 10 × AlF | 0.65 |
| 10 × AlO | 1.3 |
| 2 × F + 10 × AlO | 1.4 |

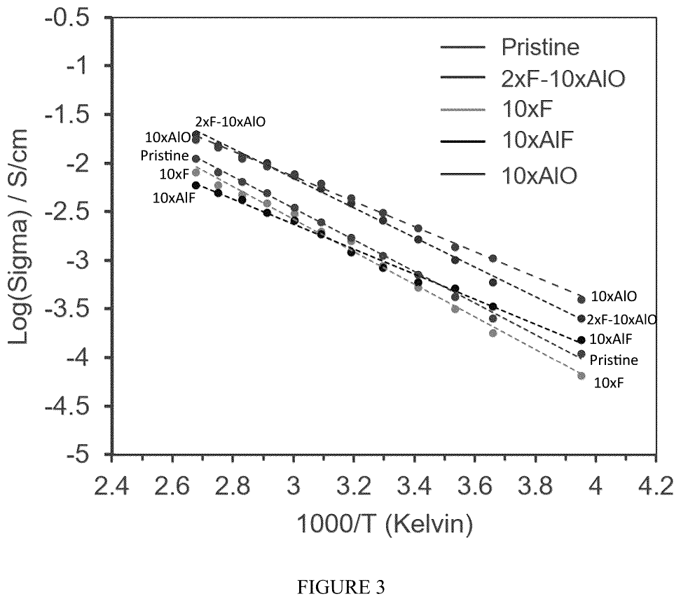

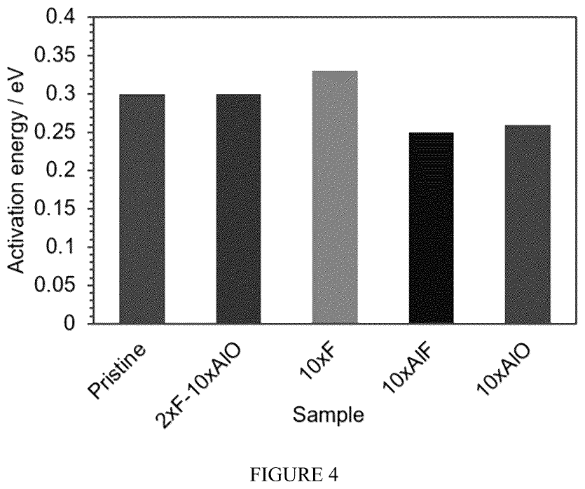

FIG. 3 is a graph of Li ion conductivity measured using electrochemical impedance spectroscopy. FIG. 4 outlines the Arrhenius activation energy for Li ion conductivity for each sample. Argyrodite-type material used for the testing was formed as an ASE from cold-pressed pellet at 150 MPa for 2 min, and EIS was completed from −20 to 100° C. under a pressure of 8 MPa. The 2xF-10xAlO and 10xAlO procedures improve the ionic conductivity. The 10xF increases the activation energy for Li+ conduction, while the 10xAlF decreases the activation energy.

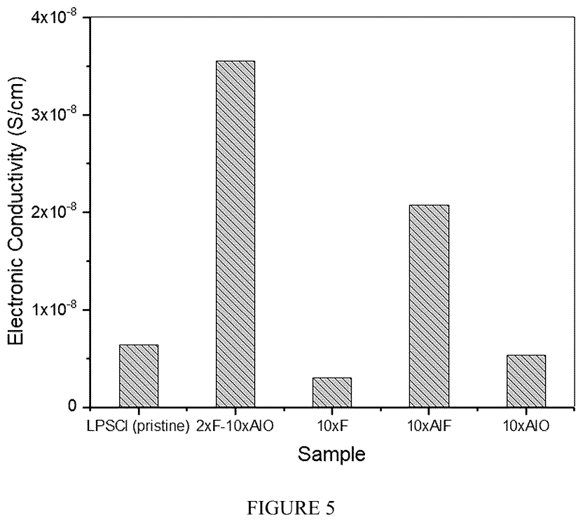

FIG. 5 is a graph of electronic conductivity measured by applying a 0.2 V DC bias across an argyrodite pellet at 25° C. The electronic conductivity of the 10xF sample is lower when compared to both the pristine and the other ALD-coated samples The insulating behavior of the 10xF coating can contribute to the observed increase in the Arrhenius activation energy.

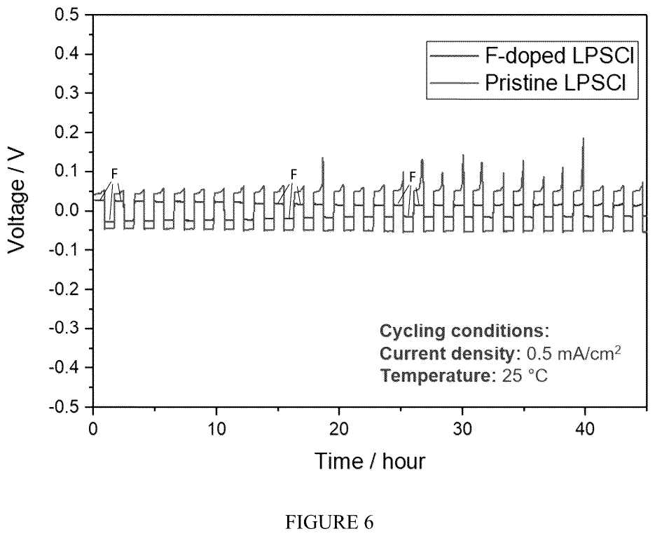

FIG. 6 is a graph of voltage versus time by applying 0.5 mA/cm² to a Li|SSE|Li symmetric cell at 25° C. FIG. 6 illustrates symmetric-cell cycling results that show the added benefits of the argyrodites with F-doping on the surface.

### Definitions

No claim element herein is to be construed under the provisions of 35 U.S.C. § 112 (f), unless the element is expressly recited using the phrase “means for.”

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

The term “or,” as used herein, is used in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is understood to convey that an element may be either X, Y, Z; X and Y; X and Z; Y and Z; or X, Y, and Z (i.e., any combination of X, Y, and Z). Thus, such conjunctive language is not generally intended to imply that certain embodiments require at least one of X, at least one of Y, and at least one of Z to each be present, unless otherwise indicated.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

Although the figures and description may illustrate a specific order of method steps, the order of such steps may differ from what is depicted and described, unless specified differently above. Also, two or more steps may be performed concurrently or with partial concurrence, unless specified differently above.

What is claimed is:

1. A method of modifying argyrodite-type material comprising:
providing an argyrodite-type material in a reactor, the argyrodite-type material having a carbonate coating thereon; and
exposing the argyrodite-type material to a first fluorine precursor for a first fluorine precursor exposure time and at a first fluorine precursor partial pressure and binding the first fluorine precursor to at least the carbonate coating;
removing at least a portion of the carbonate coating from the argyrodite-type material; and
purging the reactor of the first fluorine precursor.

2. The method of claim 1, further comprising binding the first fluorine precursor with the argyrodite-type material and forming a fluorine doped argyrodite-type material.

3. The method of claim 3, wherein the fluorine doped argyrodite-type materials comprises M-P-S-X-F, where M is a metal selected from the group consisting of Li, Mg, Na, and Ca, and X is a metal selected from the group consisting of F, Cl, Br, I, and combinations thereof.

4. The method of claim 1, wherein the first fluorine precursor is selected from the group consistent of hydrogen fluoride (HF), hydrogen fluoride-pyridine (HF-py), hexafluoroacetylacetonate (Hfac), boron trifluoride (BF₃), tungsten hexafluoride (WF₆), molybdenum hexafluoride (MoF₆), tantalum pentafluoride (TaF₅), and niobium pentafluoride (NbF₅).

5. The method of claim 1, wherein the first fluorine precursor exposure time is 45 to 120 seconds and the first fluorine partial pressure is 0.001 to 10 Torr.

6. The method of claim 1, wherein the reactor has a temperature of 100-350° C.

7. The method of claim 1, further comprising, after purging of the first fluorine precursor, performing at least one cycle of ALD depositing a capping layer on the argyrodite-type material, the capping layer comprising a metal oxide.

8. The method of claim 1, wherein the ALD depositing of the capping layer comprises exposing the
modifying the argyrodite-type material, after by atomic layer deposition process including at least one cycle of:
pulsing a second metal precursor into the reactor for a second metal precursor pulse time;
exposing the argyrodite-type material to the second metal precursor for a second metal precursor exposure time and at a second partial pressure and binding the second metal precursor;
purging the reactor of the second metal precursor;
pulsing a second co-reactant into the reactor for a second coreactant pulse time;
exposing the bound second metal precursor to the second coreactant;
forming the capping layer.

9. The method of claim 8, wherein the capping layer comprises Al₂O₃, ZrO₂, TiO₂, HfO₂, Nb₂O.

10. The method of claim 1 wherein second metal precursor is diethyl zinc (DEZ) and the second co-reactant is H₂O, further wherein the capping layer is a zinc oxide layer.

11. A method of modifying argyrodite-type material comprising:
providing an argyrodite-type material in a reactor, the argyrodite-type material having a carbonate coating thereon; and
modifying the argyrodite-type material with fluorine by atomic layer deposition process including at least one cycle of:
pulsing a first metal precursor into the reactor for a first metal precursor pulse time;
exposing the cathode to the first metal precursor for a first metal precursor exposure time and at a first partial pressure and binding the first metal precursor;
purging the reactor of the first metal precursor;
pulsing a fluorine precursor into the reactor for a first fluorine precursor pulse time;
exposing the fluorine to the first fluorine precursor for a first fluorine precursor exposure time and at a first fluorine precursor partial pressure, the first fluorine precursor reacting with the bound first metal precursor; and
purging the reactor of the first fluorine precursor;
wherein at least a portion of the carbonate coating is removed and the first fluorine precursor is doped with fluorine.

12. The method of claim 11, wherein the first metal precursor is TMA.

13. The method of claim 12, wherein the fluorine precursor is HF-py.

14. The method of claim 11, further comprising binding the first fluorine precursor with the argyrodite-type material and forming a fluorine doped argyrodite-type material.

15. The method of claim 14, wherein the fluorine doped argyrodite-type materials comprises M-P-S-X-F, where M is a metal selected from the group consisting of Li, Mg, Na, and Ca, and X is a metal selected from the group consisting of F, Cl, Br, I, and combinations thereof.

16. The method of claim 11, further comprising, after purging of the first fluorine precursor, performing at least one cycle of ALD depositing a capping layer on the doped argyrodite-type material, the capping layer comprising a metal oxide.

17. The method of claim 16, wherein the ALD depositing of the capping layer comprises exposing the
modifying the argyrodite-type material, after by atomic layer deposition process including at least one cycle of:
pulsing a second metal precursor into the reactor for a second metal precursor pulse time;
exposing the argyrodite-type material to the second metal precursor for a second metal precursor exposure time and at a second partial pressure and binding the second metal precursor;
purging the reactor of the second metal precursor;
pulsing a second co-reactant into the reactor for a second coreactant pulse time;
exposing the bound second metal precursor to the second coreactant; and
forming the capping layer.

18. The method of claim 17, wherein the capping layer comprises Al₂O₃, ZrO₂, TiO₂, HfO₂, Nb₂O.

19. The method of claim 17 wherein second metal precursor is diethyl zinc (DEZ) and the second co-reactant is H₂O, further wherein the capping layer is a zinc oxide layer.
